(19) United States
(12) Patent Application Publication
(10) Pub. No.: US 2025/0183093 A1
(43) Pub. Date: Jun. 5, 2025

(54) HYBRID SEAL FOR SEMICONDUCTOR PROCESSING CHAMBERS

(71) Applicant: Applied Materials, Inc., Santa Clara, CA (US)

(72) Inventors: Suresh GUPTA, Union City, CA (US); Siddharth Khuteta, Mountain View, CA (US); Ashish Goel, Cupertino, CA (US)

(21) Appl. No.: 18/524,955

(22) Filed: Nov. 30, 2023

(51) Int. Cl. H01L 21/687; H01J 37/32; H01L 21/67

(52) U.S. Cl. CPC H01L 21/68785; H01J 37/32715; H01L 21/67069; H01L 21/68757

(57) ABSTRACT

A substrate support assembly is disclosed herein. The substrate support assembly includes, a facility plate, a substrate support with an upper surface to support a workpiece, a seal receiving groove disposed in the facility plate and a lower surface of the substrate support, and a hybrid seal disposed in the seal receiving groove to seal between the support plate and the facility plate. The hybrid seal includes a first portion of a first material disposed in contact with the facility plate and a second portion of a second material disposed in contact with the support plate. The second portion has a thickness less than a thickness of the first portion. The second portion is laterally constrained relative to the first portion. The second portion is a different type of material from the first material and thermally shields the first material from the support plate.

### BACKGROUND

### Field

In semiconductor processing, components utilized in a semiconductor processing chamber often utilize seals to separate vacuum and ambient environments, seal gas lines, and protect different parts from process chemistry, among other usages. In some vacuum processing chambers, components are exposed to temperatures up to and exceeding 300 degrees Celsius. At such high temperatures, material choices for effective elastomeric seals become limited. Metal seals have good performance at high temperatures, but process chemistry compatibility, high compression force, surface finish requirement and difficult assembly pose a limiter on their application.

Therefore, there is a need for an improved seal suitable for use in semiconductor processing chambers.

### SUMMARY

Embodiments of the present disclosure generally relate to Application hardware for a hybrid seal within a processing chamber. In one embodiment, a substrate support assembly is disclosed herein. The substrate support assembly includes, a facility plate, a substrate support with an upper surface to support a workpiece, a seal receiving groove disposed in the facility plate and a lower surface of the substrate support, and a hybrid seal disposed in the seal receiving groove to seal between the support plate and the facility plate. The hybrid seal includes a first portion of a first material disposed in contact with the facility plate and a second portion of a second material disposed in contact with the support plate. The second portion has a thickness less than a thickness of the first portion. The second portion is laterally constrained relative to the first portion. The second portion is a different type of material from the first material and thermally shields the first material from the higher temperatures of the support plate.

In another embodiment, a substrate support assembly is disclosed herein. The substrate support assembly, includes a facility plate, a support plate, a seal receiving groove disposed in at least one of the facility plate and a lower surface of the support plate, and a hybrid seal. The hybrid seal is disposed in the seal receiving groove and provides a seal between the support plate and the facility plate. The hybrid seal includes a first portion and a second portion. The first portion has a first material disposed in contact with the facility plate and includes fluorine. The second portion includes a second material having a flat face disposed in contact with the support plate. The second portion has a thickness less than a thickness of the first portion and is laterally constrained relative to the first material. The second material has a greater molecular weight than the first material. The second material thermally shields the first material from the support plate.

In another embodiment, a processing chamber is disclosed herein. The processing chamber includes walls that partially define processing region, a vacuum source, a RF power source, and a substrate support assembly. The substrate support assembly includes a facility plate, a support plate, a seal receiving groove, and a hybrid seal. The seal receiving groove is disposed in at least one of the facility plate and a lower surface of the support plate. The hybrid seal is disposed in the seal receiving groove. The hybrid seal includes a first portion of a first material disposed in contact with the facility plate and a second portion of a second material disposed in contact with the support plate. The second portion has a thickness less than a thickness of the first portion. The second portion is laterally constrained relative to the first portion. The second portion is a different type of material from the first material and thermally shields the first material from the support plate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a cross-sectional schematic view of an exemplary plasma processing chamber according to an embodiment.

FIG. 2 is a schematic sectional view of a portion of an exemplary substrate support assembly according to an embodiment.

FIGS. 3A and 3B are schematic enlarged sectional views of a portion of an exemplary substrate support assembly according to some embodiments.

FIG. 4 is a schematic block diagram view of a method of substrate processing, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

A hybrid seal is described herein that provides reliable sealing between semiconductor processing chamber components, including those utilized at temperatures up to and exceeding 300 degrees Celsius. The hybrid seal may also be used to provide a seal in non-semiconductor processing chamber components. Although the exemplary hybrid seal is primarily described as used in a substrate support assembly, the hybrid seal may also be used with many other chamber components, such as but not limited to a showerhead to a chamber lid, a showerhead to a gas distribution plate, and a chamber lid to chamber body, among others. The hybrid seal uses a first material to thermally shield a second material when the seal is axially compressed between a hot chamber component and a cooler chamber component. The first material may optionally include a flat that provides a larger and more effective sealing surface.

When used in a substrate support assembly, the hybrid seal enables a wide range of temperatures during operation of an electrostatic chuck (ESC). The hybrid seal may be used between a hot component and cool component to maintain process gases in specific regions. The hybrid seal can be disposed between a hot support plate and a cooler facility plate to provide an effective high temperature vacuum seal. The hybrid seal is configured to have a one portion thermally shield another portion of the seal. In some examples, a portion of the hybrid seal enters a melt phase when exposed to high temperatures, but has a melt viscosity such that the hybrid seal still maintains an effective hermetic seal. Embodiments described herein enable maintaining the pressure differential between a processing region and an internal cavity of the support plate assembly during processing conditions and temperatures with a multi-material polymer seal. The processing temperatures (i.e., temperature of the workpiece or support plate) include to temperatures at or greater than 300 degrees Celsius at the support plate.

Although the substrate support assembly is described below in an etch processing chamber, the substrate support assembly may be utilized in other types of plasma processing chambers, such as physical vapor deposition chambers, chemical vapor deposition chambers, ion implantation chambers, among others, and other systems where processing a substrate maintained at the processing temperature is desirable. It is to be noted however, that the substrate support assemblies and chamber components described herein may be utilized to advantage at other processing temperatures.

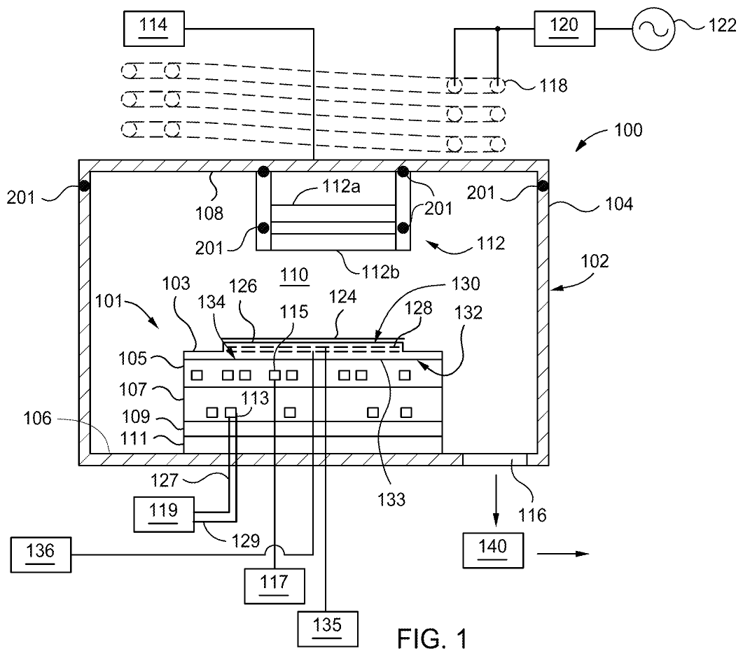

FIG. 1 is a cross-sectional schematic view of an exemplary processing chamber 100, shown configured as an etch chamber, having a substrate support assembly 101. As mentioned above, the substrate support assembly 101 may be utilized in other types of plasma processing chambers, for example plasma treatment chambers, annealing chambers, physical vapor deposition chambers, chemical vapor deposition chambers, and ion implantation chambers, among others. A substrate 124 is disposed on the substrate support assembly 101 while the substrate 124 is processed, for example, etched, in the processing chamber 100.

The processing chamber 100 includes a chamber body 102 having sidewalls 104, a bottom 106 and a lid 108 that enclose a processing region 110. An injection apparatus 112 is coupled to the sidewalls 104 and/or lid 108 of the chamber body 102. A gas panel 114 is coupled to the injection apparatus 112 to allow process gases to be provided into the processing region 110. The injection apparatus 112 may be one or more nozzle or inlet ports. Process gases, along with any processing by-products, are removed from the processing region 110 through an exhaust port 116 formed in the sidewalls 104 or bottom 106 of the chamber body 102. The exhaust port 116 is coupled to a pumping system 140, which includes throttle valves, a vacuum source, and pumps utilized to control the vacuum levels within the processing region 110. Processing by-products are also removed through the exhaust port 116 using the pumping system 140.

The injection apparatus 112 may include a showerhead 112a and a gas distribution plate 112b. The distribution plate 112b is disposed between the processing region 110 and the showerhead 112a.

The process gases may be energized to form a plasma within the processing region 110. The process gases may be energized by capacitively or inductively coupling RF power to the process gases. In one embodiment, which can be combined with other embodiments described herein, depicted in FIG. 1, a plurality of coils 118 are disposed above the lid 108 of the processing chamber 100 and coupled through a matching circuit 120 to an RF power source 122.

The substrate support assembly 101 is disposed in the processing region 110 below the injection apparatus 112. The substrate support assembly 101 includes an electrostatic chuck (ESC) 103 and a support plate 105. The support plate 105 is coupled to the ESC 103 and a facility plate 107. In one embodiment that may be combined with other embodiments the ESC 103 is a ceramic puck integrated into the support plate 105. In one embodiment, that may be combined with other embodiments, the support plate 105 is screwed into the facility plate 107. The facility plate 107, supported by a ground plate 111, is configured to facilitate electrical, cooling, heating, and gas connections within the substrate support assembly 101. The ground plate 111 is supported by the bottom 106 of the processing chamber. A dielectric plate 109 electrically insulates the facility plate 107 from the ground plate 111.

The substrate 124 is disposed on the ESC 103 in the processing region 110. The substrate 124 may be heated by the heaters disposed in the substrate support assembly 101 and/or the plasma present in the processing chamber 100.

The support plate 105 and/or the facility plate 107 includes a base channel 115 fluidly coupled to a chiller 117. The chiller 117 provides a heat transfer fluid, such as a refrigerant, to the base channel 115 so that the support plate 105, and consequently, the substrate 124, may be maintained at a predetermined temperature. The facility plate 107 may include a facility channel 113 fluidly coupled to a heating fluid source 119. The heating fluid source 119 provides facility fluid to the facility channel 113 so that the facility plate 107 is maintained a predetermined temperature.

The heating fluid source 119 is in fluid communication with the facility channel 113 via a facility inlet conduit 127 connected to the facility channel 113 and via a facility outlet conduit 129 connected to the facility channel 113 such that the facility plate 107 is maintained at a predetermined temperature. The heating fluid source 119 provides the heat transfer fluid, which is circulated through the facility channel 113 of the facility plate 107. The heat transfer fluid is generally dielectric or electrically insulative so that an electrical path is not formed through the heat transfer fluid when circulated through the substrate support assembly 101. A non-limiting example of a suitable facility fluid includes fluorinated heat transfer fluids such as perfluoropolyether (PFPE) fluids. The heat transfer fluid flowing through the facility channel 113 enables the facility plate 107 to be maintained at the predetermined temperature less than the support plate 105.

The ESC 103 has an upper surface 130 and a bottom surface 132 opposite the upper surface 130. In one embodiment, which can be combined with other embodiments described herein, the ESC 103 is fabricated from a ceramic material, such as alumina (Al₂O₃), aluminum nitride (AlN) or other suitable material. The upper surface 130 is adapted to support a workpiece, for example to support the substrate 124.

A bond layer 133 is provided at an interface between the bottom surface 132 of the ESC 103 and a top surface 134 of the support plate 105. The ESC 103 may be made of alumina (Al₂O₃) or aluminum nitride (AlN). The support plate 105 may be made of aluminum (Al), molybdenum (Mo), a ceramic, or combinations thereof. The bond layer 133 allows strain to be absorbed due to small differences in the coefficient of thermal expansion (CTE) of the ESC 103 and support plate 105 from temperatures of about 200 degrees Celsius to about 400 degrees Celsius during operation.

The ESC 103 includes a chucking electrode 126 disposed therein. The chucking electrode 126 may be configured as a mono polar or bipolar electrode, or other suitable arrangement. The chucking electrode 126 is coupled through an RF filter and the facility plate 107 to a chucking power source, which provides a DC power to electrostatically secure the substrate 124 to the upper surface 130 of the ESC 103. The RF filter prevents RF power utilized to form a plasma (not shown) within the processing chamber 100 from damaging electrical equipment or presenting an electrical hazard outside the chamber.

The ESC 103 includes one or more resistive heaters 128 embedded therein. The resistive heaters 128 are utilized to control the temperature of the ESC 103, such that processing temperatures suitable for processing a substrate 124 disposed on the upper surface 130 of the substrate support assembly 101 may be maintained. The resistive heaters 128 are coupled through the facility plate 107 and an RF filter to a heater power source 135. The RF filter prevents RF power utilized to form a plasma (not shown) within the processing chamber 100 from damaging electrical equipment or presenting an electrical hazard outside the chamber. The heater power source 136 may provide 500 watts or more power to the resistive heaters 128. The heater power source includes a controller (not shown) utilized to control the operation of the heater power source 136, which is generally set to heat the substrate 124 to a predetermined temperature. In one embodiment, which can be combined with other embodiments described herein, the resistive heaters 128 include a plurality of laterally separated heating zones, wherein the controller enables at least one zone of the resistive heaters 128 to be preferentially heated relative to the resistive heaters 128 located in one or more of the other zones. For example, the resistive heaters 128 may be arranged concentrically in a plurality of separated heating zones. The resistive heaters 128 maintain the ESC 103, and consequently the substrate 124, at a processing temperature suitable for processing. In one embodiment, which can be combined with other embodiments described herein, the ESC 103 is maintained at a temperature between about 100 degrees Celsius to about 400 degrees Celsius, for example, about 360 degrees Celsius. The ESC 103 is generally maintained at a temperature greater than that of the facility plate 107.

In one embodiment, which can be combined with other embodiments described herein, the processing temperature is greater than about 10 degrees Celsius. For example, the processing temperature is between about 10 degrees Celsius to about 375 degrees Celsius, for example, about 360 degrees Celsius.

The processing chamber 100 includes a plurality of seals. The seals may be used in various locations. For example, a hybrid seal 201 may be used between the sidewalls 104, and the lid 108. In another example, the hybrid seal 201 may be placed between the injection apparatus 112 and the lid 108. In another example, the hybrid seal 201 may be placed between the gas distribution plate 112b and the showerhead 112a. In another example, the support assembly 101 may also include seals between the different components, 105, 107, 109, 111. The above examples may be used individually or in combination. The examples provide potential places the hybrid seal 201 may be implemented, but other locations are also contemplated. The hybrid seal 201 is discussed in more detail below.

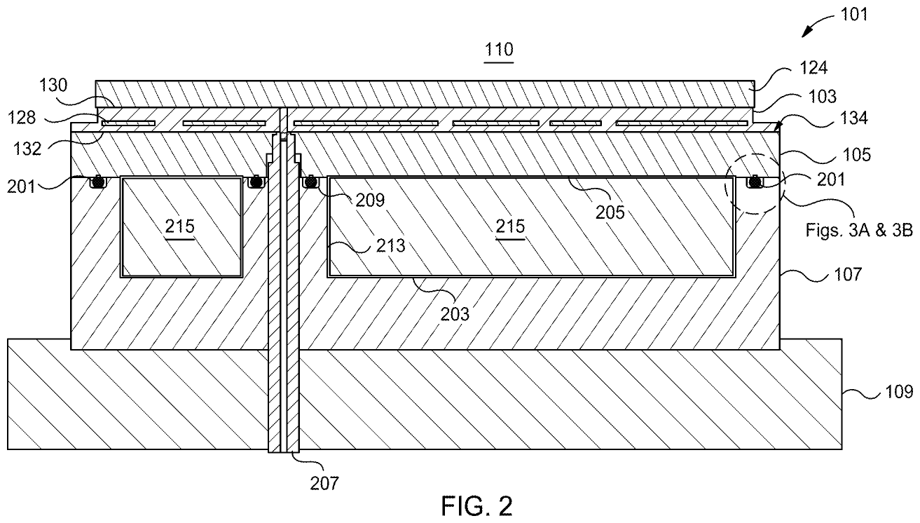

FIG. 2 is a schematic sectional view of a portion of an exemplary substrate support assembly 101 according to an embodiment. The substrate support assembly 101 is configured to enable operation of ESC 103 so that a substrate 124 disposed thereon is maintained at the processing temperature. The ESC 103, the support plate 105, the facility plate 107, and the dielectric plate 109 are shown in FIG. 2.

As shown, the substrate support assembly 101 includes one or more hybrid seals 201. The hybrid seal 201 is disposed in a seal receiving groove 209. In one embodiment, the seal receiving groove 209 maybe disposed in the facility plate 107. In one embodiment, which may be combined with other embodiments, the seal receiving groove 209 is disposed in the support plate 105. The seal receiving groove 209 is described in more detail below.

The hybrid seal 201 seals a cavity 203 of the facility plate 107 from the process region 110. The hybrid seal 201 seals the cavity 203 by contacting the support plate 105 and the facility plate 107. The hybrid seal 201 may be located around an axis A1 of the substrate support assembly 101. In one embodiment, which may be combined with other embodiments, the substrate support assembly 101 includes additional hybrid seals 201 around one or more ports 213. For example, the facility plate 107 includes one or more ports 213. The ports 213 include an aperture for a lift pin 207 to pass through the facility plate 107, the support plate 105, the ESC 103, and lift the workpiece from the upper surface 130 of the ESC 103.

The hybrid seal 201 is used to seal the cavity 203 from the process region 110 by being disposed around a lift pin axis P1 of the port 213.

The cavity 203 is defined by the support plate 105 and the facility plate 107. The cavity 203 may be utilized to place measuring components, temperature components, or other pieces of equipment, to enhance the capabilities of the substrate support assembly 101. The cavity 203 also aids in reducing the thermal energy transferred from the support plate 105 to the dielectric plate 109. The cavity 203 is at a pressure different than the pressure of the processing region 110. For example, the processing region 110 may be at a pressure less than 760 Torr, while the cavity 203 is at about 760 Torr. The hybrid seal 201 enhances the ability of the support plate 105 to not leak matter into the processing region 110 when the processing region 110 is under vacuum.

The cavity 203 is partially filled by a cooling plate 215. The hybrid seal 201 help reduce the interaction between the cooling plate 215 and the harmful process gases. The reduction is accomplished by keeping the process gases out of the cavity 203.

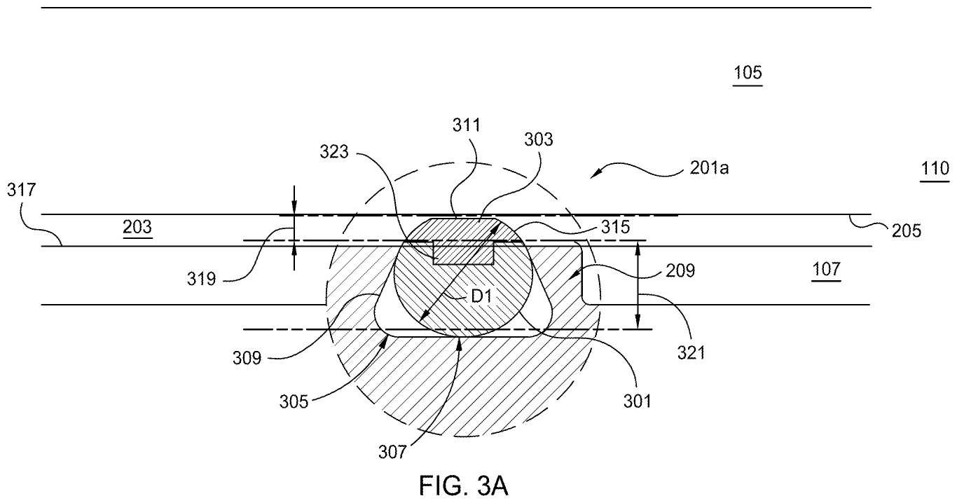

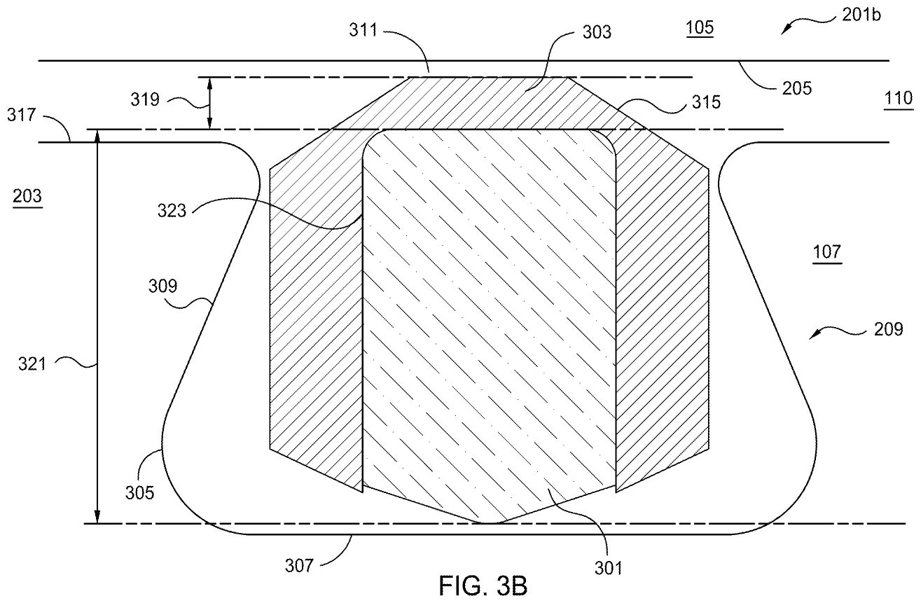

FIGS. 3A and 3B are schematic enlarged sectional views of a portion of an exemplary substrate support assembly 101 according to some embodiments.

As shown in FIG. 3A, a hybrid seal 201a is disposed in the seal receiving groove 209 of the facility plate 107. The hybrid seal 201a provides a seal between the support plate 105 and the facility plate 107. The hybrid seal 201 is disposed within the seal receiving groove 209. The seal receiving groove 209 is disposed in at least one of the facility plate 107 and the lower surface 205 of the support plate 105. The seal receiving groove 209 extends from a first surface 317. In some embodiments, the first surface 317 is a surface of the facility plate 107. The seal receiving groove 209 includes sidewalls 309 and a base surface 307. In one embodiment which may be combined with other embodiments, the sealing groove is in the facility plate 107. In one embodiment which may be combined with other embodiments, the sealing groove is in the support plate 105. In one embodiment which may be combined with other embodiments, the support plate 105 and the facility plate 107 have a seal receiving groove 209.

The seal receiving groove 209 is configured to constrain the hybrid seal 201a partially within at least one of the support plate 105 and/or the facility plate 107. As shown, the seal receiving groove 209 has a dovetail shape, but other shapes are contemplated. For example, the seal receiving groove 209 may have a rectangular shape, a semi-circular shape, and/or a triangular shape. The sealing groove 209 includes one or more radii 305, according to some embodiments.

The hybrid seal 201a includes a first portion 301 and a second portion 303. In one embodiment which may be combined with other embodiments, the hybrid seal 201a has a diameter D1 of about 100 mils to 200 mils, for example about 140 mils. The hybrid seal 201a includes a connection feature 323.

The connection feature 323 is an interlocking geometry of the first portion 301 and the second portion 303 of the hybrid seal 201a. The connection feature 323 laterally constrains the second portion 303 relative to the first portion 301. The second portion 303 is laterally constrained relative to the first portion 301 by the connection feature 323. The connection feature 323 is configured to separate the support plate 105 from the first portion 301 by about 15 mils or greater. In one or more embodiments which may be combined with other embodiments, connection feature 323 is where the second portion 303 extends into the first portion 301. The first portion 301 partially surrounds the second portion 303 where the second portion 303 extends into the first portion 301. In one or more embodiments which may be combined with other embodiments, the first portion 301 separates the sidewalls 309 from second portion 303. The connection feature 323 is a snap fit between the first portion 301 and the second portion 303. A snap fit includes a connection where one portion is able to constrain another portion through geometry. For example, a snap fit does not require a chemical bond to constrain a portion.

In one embodiment which may be combined with other embodiments, the connection feature 323 is a recess. For example, one of the first portion 301 and the second portion 303 of the hybrid seal 201a includes the recess and the other portion includes a corresponding projection interleaved with the recess.

The hybrid seal 201a also includes the flat face 311. The flat face 311 is a surface of the second portion 303. The flat face 311 forms a plane about parallel to the lower surface 205 of the support plate 105. In one embodiment, which may be combined with other embodiments, the hybrid seal 201a has substantially circular cross section. The flat face has an orientation perpendicular to a centerline of the hybrid seal 201a.

The first portion 301 is disposed in contact with the facility plate 107. The first portion 301 is separated from the support plate 105 by the second portion 303. The second portion 303 is between the support plate 105 and the first portion 301. The first portion 301 includes a first material. The first portion 301 includes a thickness 321. The thickness 321 is defined as the distance the first portion 301 extends from the base surface 307.

The first material is a polymer having branching carbon to carbon chains. In one embodiment that may be combined with other embodiments the first material is a carbon and fluorine based elastomer. In one embodiment that may be combined with other embodiments, the first material is a perfluoroelastomer (FFKM). In one embodiment that may be combined with other embodiments, the first material is comprised of a fluoroelastomer (FKM). The first material has a density of about 100 to about 120 grams per mole. The first material includes monomers in the chemical structure. The monomers are attached to branching carbon and fluorine compounds. The monomers may include tetrafluoroethylene (TFE), perfluoromethyl vinyl ether (PMVE) and/or a cure site monomer (CSM). The monomers form side chains in the chemical structure for enhanced elasticity and sealing capability. The first material has a tensile strength of about 1000 PSI to about 3200 PSI. The first material has a melting temperature of about 260 to about 325 degrees Celsius.

The second portion 303 is disposed in contact with the support plate 105. The second portion 303 includes a second material and a thickness 319. The thickness 319 is the distance between the first portion 301 and a lower surface 205 of the support plate 105 in a direction perpendicular to the plane of the lower surface 205. The second portion 303 includes an exterior surface 315. The exterior surface 315 is the plasma side of the second portion 303 and is exposed to the processing region 110 and the atmosphere of the cavity 203.

The second material is comprised of a polymer having linear branching carbon to carbon chains. The second material includes carbon and fluorine. In one embodiment that may be combined with other embodiments the second material is polytetrafluoroethylene (PTFE). In one embodiment that may be combined with other embodiments the second material may be Polyether ether ketone (PEEK), polyimide, or any combination thereof. The second material has a number-average molecular weight of about 1.4×10⁴ to about 1×10¹⁰ grams per mole. The second material has a number-average molecular weight greater than the first material. The first material of the first portion 301 is a different type than the second material of the second portion 303. For example, the second material has a 5% or greater concentration of fluorine than the first material. The second material has a density of about 2.00 to about 2.40 grams per cubic centimeter. In some embodiments, the second material has a density of 25% or more than the first material. The second material has a tensile strength of about 1400 PSI to about 6100 PSI. The second material has a tensile strength of 5% or greater than the first material. The second material is more rigid than the first material. The second material has a melting temperature greater than the first material. For example, the melting temperature of the second material is greater than the melting temperature of first material by 5 degrees Celsius or more. The second material has a melt viscosity of about 10¹⁰ to about 10¹⁸ Pascal seconds at 380 degrees Celsius and a melt flow index (MFI) of less than 0.1 g/10 min at 372° C. using a 5 kg load. The second material has enhanced plasma resistivity.

As shown in FIG. 3B, a hybrid seal 201b is disposed in the seal receiving groove 209 of the facility plate 107. The hybrid seal 201b is similar to the hybrid seal 201a of FIG. 3A.

The connection feature 323 of the hybrid seal 201b is an interlocking geometry of the first portion 301 and the second portion 303 of the hybrid seal 201a. The connection feature 323 of the hybrid seal 201b forms and inverted U shape with second portion 303. The connection feature 323 laterally constrains the second portion 303 relative to the first portion 301. In one or more embodiments which may be combined with other embodiments, the connection feature 323 is where the second portion 303 extends into the seal receiving groove 209 and around the first portion 301. For example, the first portion 301 is in contact with the base surface 307 and is separated from the sidewalls 309 by the second portion 303.

The hybrid seal 201a, 201b as described in FIGS. 3A and 3B enables enhanced sealing of the substrate support assembly 101 (FIG. 2). The high melt viscosity of the second portion 303 enables sealing when the temperature of the support plate 105 is above 325 degrees Celsius. The elastomeric properties of the first portion 301 also enhance the sealing ability of the hybrid seal 201. When used in conjunction, the second portion 303 operates as a thermal break between the support plate 105 and the first portion 301. The second material of the second portion 303 includes characteristics for thermally shielding the first portion 301 from the support plate 105. The increased elasticity of the first portion ensures a pressure differential is maintained between the processing region 110, and the cavity 203 within the substrate support assembly 101 (FIG. 2). The enhanced sealing is achieved because the melt phase characteristics of the second material of the second portion 303 prevent deformation of the second portion 303 at processing temperatures and plasma conditions that would otherwise compromise a single material seal.

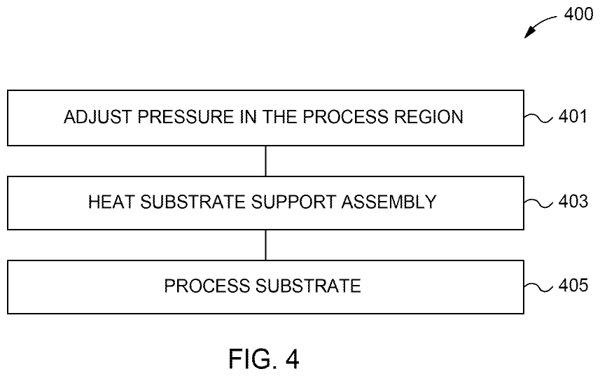

FIG. 4 is a schematic block diagram view of a method of substrate processing, according to one or more embodiments.

Operation 401 of a method 400, the pressure of the processing region 110 (FIG. 1) is adjusted. Adjusting the pressure creates a pressure differential between the processing region 110 and the internal cavity 203 of the substrate support assembly 101. In some embodiments, adjusting the pressure includes applying a vacuum to the processing region 110.

At operation 403, the substrate support assembly 101 is heated. The substrate support assembly 101 is heated by one or more of a capacitively induced plasma, an inductively induced plasma, and/or resistive heating elements within the substrate support assembly 101. During the heating process, the support plate 105 may reach a temperature of 350 degrees Celsius, or more. Previous elastomeric seals were not capable of maintaining the pressure differential because the heat and/or the plasma caused the seals to fail. Seal failure included seal deformation, erosion, and vaporization due to heat and plasma exposure.

At operation 405, a substrate on the substrate support assembly 101 is processed. The processing may be an etch process, an anneal process, a plasma etch process, a plasma anneal process, a deposition, process, but other processes are contemplated.

Benefits of the present disclosure include enhanced seal durability, life span, heat resistance, and plasma resistance. The enhancements to the seal increase throughput and efficiency by reducing chamber downtime.

It is contemplated that one or more aspects disclosed herein may be combined. As an example, one or more aspects, features, components, operations and/or properties of the processing chamber 100, the substrate support assembly 101, the hybrid seal 201a 201b, and/or the method 400 maybe be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A substrate support assembly, comprising:
a facility plate;
a support plate having an upper surface adapted to support a workpiece;
a seal receiving groove disposed in at least one of the facility plate and a lower surface of the support plate; and
a hybrid seal disposed in the seal receiving groove and providing a seal between the support plate and the facility plate, the hybrid seal comprising:
a first portion comprised of a first material disposed in contact with the facility plate; and
a second portion comprised of a second material disposed in contact with the support plate, the second portion having a thickness less than a thickness of the first portion, the second portion laterally constrained relative to the first portion, the second material being a different type of material from the first material, the second material thermally shielding the first material from the support plate.

2. The substrate support assembly of claim 1, wherein the first portion is separated from the support plate by at least 20 mils.

3. The substrate support assembly of claim 1, wherein the hybrid seal has a substantially circular cross section.

4. The substrate support assembly of claim 1, wherein the second material is polytetrafluoroethylene (PTFE) and the first material is a perfluoroelastomer.

5. The substrate support assembly of claim 1, wherein the first material includes monomers attached to branching carbon and fluorine compounds.

6. The substrate support assembly of claim 1, wherein the second material has a melt viscosity greater than the first material.

7. The substrate support assembly of claim 1, wherein the second portion is in an inverted U shape.

8. The substrate support assembly of claim 3, wherein the second portion has a flat face having an orientation perpendicular to a centerline of the hybrid seal, the flat face disposed in contact with the support plate.

9. The substrate support assembly of claim 1, wherein one of the first or second portions of the hybrid seal includes a recess and the other portion includes a corresponding projection interleaved with the recess.

10. A substrate support assembly, comprising:
a facility plate;
a support plate;
a seal receiving groove disposed in at least one of the facility plate and a lower surface of the support plate; and
a hybrid seal disposed in the seal receiving groove and providing a seal between the support plate and the facility plate, the hybrid seal comprising:
a first portion comprised of a first material disposed in contact with the facility plate, the first material including fluorine; and
a second portion comprised of a second material having a flat face disposed in contact with the support plate, the second portion having a thickness less than a thickness of the first portion and laterally constrained relative to the first material, the second material having a greater molecular weight than the first material, the second material thermally shielding the first material from the support plate.

11. The substrate support assembly of claim 10, wherein the second portion is in an inverted U shape.

12. The substrate support assembly of claim 10, wherein one of the first or second portions of the hybrid seal includes a recess and the other portion includes a corresponding projection interleaved with the recess.

13. The substrate support assembly of claim 10, wherein the flat face is parallel to a lower surface of the support plate.

14. The substrate support assembly of claim 10, wherein the second material is PTFE and the first material is a perfluoroelastomer.

15. The substrate support assembly of claim 10, wherein the facility plate and the support plate define a cavity within the facility plate.

16. The substrate support assembly of claim 15, wherein the hybrid seal is configured to maintain a pressure in the cavity.

17. A processing chamber comprising:
walls that partially define processing region;
a vacuum source;
a RF power source; and
a substrate support assembly, comprising:
a facility plate;
a support plate having an upper surface;
a seal receiving groove disposed in at least one of the facility plate and a lower surface of the support plate; and
a hybrid seal disposed in the seal receiving groove and providing a seal between the support plate and the facility plate, the hybrid seal comprising:
a first portion comprised of a first material disposed in contact with the facility plate; and
a second portion comprised of a second material disposed in contact with the support plate, the second portion having a thickness less than a thickness of the first portion, the second portion laterally constrained relative to the first portion, the second material being a different type of material from the first material, the second material thermally shielding the first material from the support plate.

18. The processing chamber of claim 17, wherein the second material comprises a plasma side configured to separate a plasma from the first material.

19. The processing chamber of claim 17, wherein the first material is separated from the support plate by at least 20 mils.

20. The processing chamber of claim 17, wherein the second portion has a flat face having an orientation perpendicular to a centerline of the hybrid seal, the flat face disposed in contact with the support plate.
